(19) United States
(12) Patent Application Publication
(10) Pub. No.: US 2009/0002006 A1
(43) Pub. Date: Jan. 1, 2009

(54) MANUFACTURING METHOD OF SEMICONDUCTOR DEVICE AND SEMICONDUCTOR MANUFACTURING APPARATUS

(75) Inventor: Yoshiaki Sugizaki, Oita-ken (JP)

Correspondence Address: AMIN, TUROCY & CALVIN, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/145,785

(22) Filed: Jun. 25, 2008

(30) Foreign Application Priority Data
Jun. 25, 2007 (JP) 2007-166703

(51) Int. Cl. G01R 31/28; H05K 13/04; G01R 31/02

(52) U.S. Cl. 324/754; 29/593; 29/729; 257/790

(57) ABSTRACT

In one aspect of the present invention, a manufacturing method of a semiconductor device may include performing an electrical test on a plurality of electronic components on a wafer, generating a mapping data set including category information representing categories of the respective electronic components based on the electrical test result and position information representing positions of the respective electronic components in the wafer, forming bumps on the plurality of electronic components at wafer level in various bump layouts employed in accordance with the categories assigned to the respective electronic components, with reference to the mapping data set, and dicing the wafer to separate the plurality of electronic components into individual chips, after forming the bumps.

### CROSS REFERENCE TO RELATED APPLICATION

This application is based upon and claims the benefit of priority from Japanese Patent Application No. 2007-166703, filed on Jun. 25, 2007, the entire contents of which are incorporated herein by reference.

### BACKGROUND

One of techniques having heretofore been used for electronic components is for changing the characteristics of electronic components by changing the wire bonding layouts in the electronic components, especially in semiconductor packaging.

However, the technique is not a technique for correcting the characteristics of the electronic components on the basis of the result of an electrical test at a wafer level, but a technique of employing various bonding layouts for the electronic components in order to provide the electronic components with various characteristics.

In other words, the above technique is a technique capable of changing characteristics of electronic components into desirable ones even after the electronic components has been diced from a wafer and thereby separated into individual chips, by designating what bonding layouts to employ in the respective electronic components without performing processes including categorizing the electronic components on the basis of a test result. This can be implemented because the electronic components before wire bonding are potentially capable of accepting any bonding options.

However, in the case where electronic components are selected on the basis of an electrical test result conducted at a wafer level before a bonding process, each electronic component cannot accept any type of bonding options. Accordingly, the electronic components have to be previously categorized on the basis of the electrical test result. (refer to Japanese Patent Application Publication No. Hei 9-148331, for example)

Specifically, the electronic components need to be classified into the categories when being picked up from a dicing tape after being separated into individual chips by dicing.

Incidentally, while electronic components are picked up from a dicing tape, the dicing tape needs to be stretched in order to prevent adjacent components from coming into contact with each other, in general. This deteriorates the accuracy of the position coordinates of the respective electronic components.

In electronic components of relatively fine chips, this accuracy deterioration causes a serious problem that an electronic component of a wrong category may possibly be accidentally picked up. This problem is especially serious in the case where a pick-up device is introduced multiple times to pick up the electronic components by category so that one lot of electronic components can be separated into the assigned categories. In this case, a certain chip isolated after the picking-up of its surrounding chips is to be picked. Accordingly, nothing can compensate for the inaccurate position information.

As a result, a production yield of semiconductor devices decreases.

Meanwhile, as a trimming technique to be employed at wafer level, commonly used is a technique of fusing to cut some wires on the electronic components with a laser beam.

However, laser machining required in this technique is costly and needs to be performed on the chip basis. Accordingly, if this technique is employed to manufacture low-cost electronic components of fine chips, the proportion of the cost for the laser machining to the entire manufacturing cost becomes relatively high.

### SUMMARY

Aspects of the invention relate to an improved manufacturing method of a semiconductor device and semiconductor manufacturing apparatus.

In one aspect of the present invention, a manufacturing method of a semiconductor device may include performing an electrical test on a plurality of electronic components on a wafer, generating a mapping data set including category information representing categories of the respective electronic components based on the electrical test result and position information representing positions of the respective electronic components in the wafer, forming bumps on the plurality of electronic components at wafer level in various bump layouts employed in accordance with the categories assigned to the respective electronic components, with reference to the mapping data set, and dicing the wafer to separate the plurality of electronic components into individual chips, after forming the bumps.

In another aspect of the invention, a semiconductor manufacturing apparatus may include, a wafer mounting stage configured to mount thereon a wafer on which a plurality of electronic components are formed; a bonder unit which supplies a bump material to the plurality of electronic components, a memory which stores therein bump layout information in association with category information included in the mapping data set on the wafer, the bump layout information representing various bump layouts to be employed in electronic components of the same kind in accordance with the respective categories, and a controller supplied with the mapping data set and controlling the wafer mounting stage and the bonder unit, wherein the controller reads out the bump layout information from the memory, and controls the bonder unit and the wafer mounting stage in accordance with the mapping data set and the bump layout information so that the plurality of electronic components are bumped in various bump layouts employed in accordance with the categories assigned to the respective electronic components.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a block diagram showing an overall configuration example of a semiconductor manufacturing apparatus used for implementing the manufacturing method according to the first embodiment.

FIG. 2 is a flowchart showing the manufacturing method of a semiconductor device according to the first embodiment.

FIG. 3 is a plan view of an electronic component on a wafer according to the first embodiment.

FIG. 4 is an enlarged view showing a pair of interdigitated electrodes which is configured of capacitor electrodes 14A and 14B, upper actuation electrodes 10 and lower actuation electrodes 11 to 13.

FIG. 5 shows a structure in which the chip (electronic component) 5 is flip-chip bonded to a circuit board 30.

FIG. 6 is a block diagram of a bumping machine according to a second embodiment.

FIG. 7 is a flowchart showing an operation flow of the bumping machine according to the first embodiment.

FIGS. 8 and 9 are cross sectional view of showing that two electronic components 5A and 5B are bonded.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

An embodiment of the present invention relates to a manufacturing method of a semiconductor device in which electronic components are flip-chip bonded to a circuit board.

In the embodiment of the present invention, an electrical test is performed on multiple electronic components in a wafer, at wafer level. The electronic components are respectively assigned with categories based on the electrical test, and thereby a mapping data set including category information is generated.

The electronic components in the wafer are bumped at a wafer level according to the mapping data including category information. At this time, different bump layouts are employed for the respective categories of the electronic components.

Thus, in this embodiment, the electronic components can be categorized at wafer level where position information on the electronic components retains accuracy.

After being bumped, the electronic components are separated into individual chips, the resultant chips are flip-chip bonded to respective circuit boards.

In this embodiment, the electronic components are bumped in the bump layouts depending on the categories, respectively. Accordingly, in a semiconductor device in which an electronic component is flip-chip bonded to a circuit board, the presence/absence of a bump can be used to change a connection condition between the circuit board and the electronic component, that is, a bonding option between the circuit board and the electronic component.

Thus, according to this embodiment, trimming for adjusting or restoring functions of the electrical characteristics of the electronic components can be performed at low cost.

In the embodiment of the present invention, description will be given of a semiconductor manufacturing apparatus (a bumping machine) for implementing the above manufacturing method

### FIRST EMBODIMENT

In the first embodiment, a manufacturing method of semiconductor device will be explained.

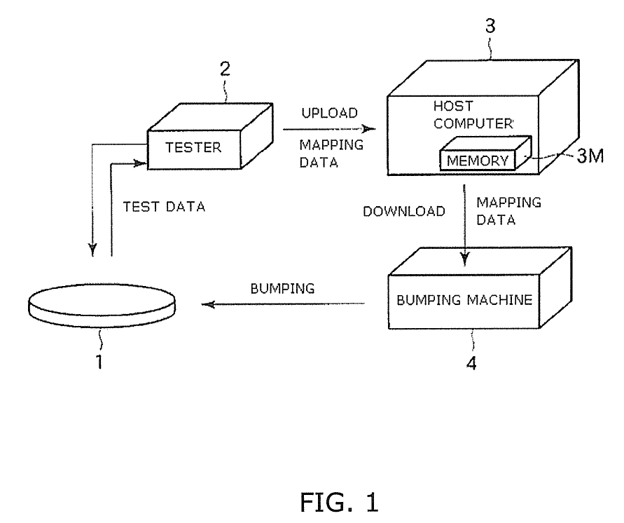

Hereinafter, description will be given of a manufacturing method of a semiconductor device according to the embodiment of the present invention with reference to FIGS. 1 to 5.

FIG. 1 is a block diagram showing an overall configuration example of a semiconductor manufacturing apparatus used for implementing the manufacturing method according to this embodiment. The configuration example shown in FIG. 1 includes a tester 2, a host computer 3 and a bumping machine 4. The tester 2 performs electrical tests on a wafer 1 on which multiple electronic components 5 are formed. A mapping data set based on an electrical test result is uploaded to the host computer 3. According to the mapping data set downloaded from the host computer 3, the bumping machine 4 forms bumps on the electronic components 5 on the wafer 1.

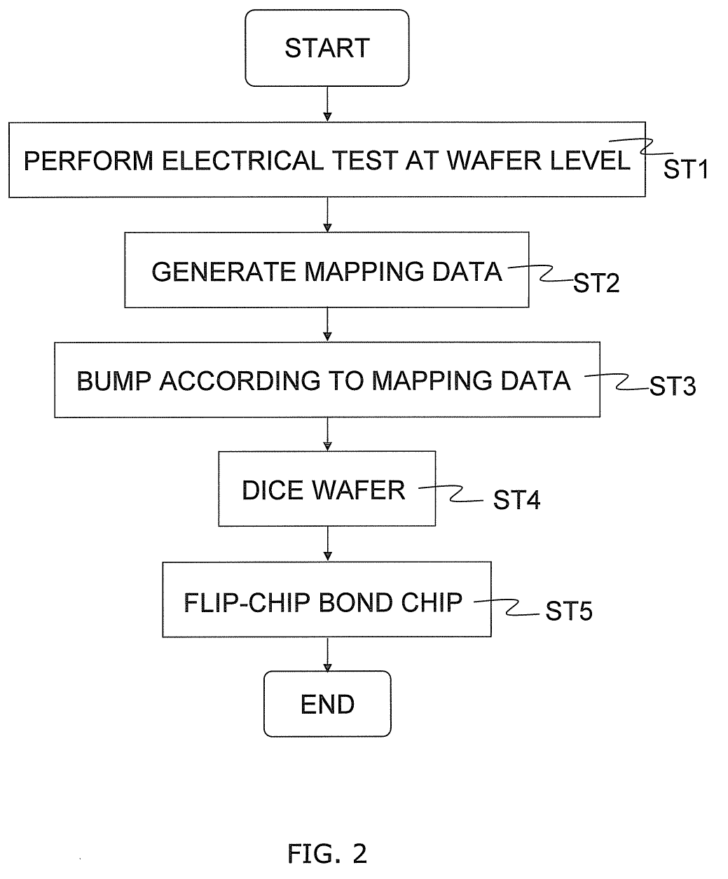

FIG. 2 is a flowchart showing the manufacturing method of a semiconductor device according to this embodiment.

Hereinafter, detailed description will be given of the manufacturing method according to this embodiment with reference to FIGS. 1 to 3.

Firstly, the tester 2 performs an electrical test e.g. an actuation voltage test on the electronic components 5 formed on the wafer 1, at wafer level (ST1). Note that the electronic components 5 are, for example, microelectro mechanical systems (MEMS) devices or large scale integrated circuits (LSIs) which constitute a sensor, an RF device, a switch, and a variable capacitor or the like.

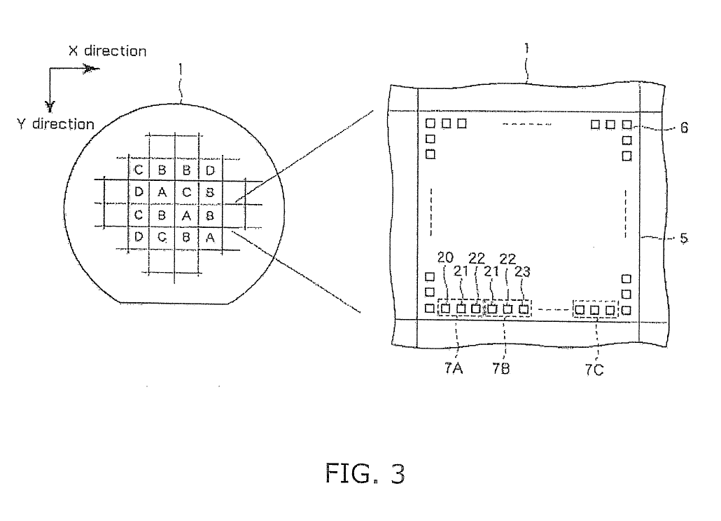

This electrical test is performed on the electronic components 5 formed on the wafer 1, sequentially in the x direction and the y direction based on the x-y coordinate system as shown in FIG. 3. Then, the multiple electronic components 5 are categorized on the basis of the electrical test result, and thereby, each electronic component is assigned one of category information pieces A to D. Among the category information pieces A to D, each of the categories A to C indicates that the electronic component is of good quality, while the category D indicates that the electronic component is completely defective. Moreover, the categories A to C respectively correspond to different levels of electrical characteristics, such as actuation voltage levels. On each of the electronic components 5 assigned the categories A to C, trimming suitable for the assigned category is performed for adjusting or restoring functions for providing its electrical characteristics.

Thus, on the wafer 1, not only bonding pads 6 (hereinafter referred to as normal pads) for inputting and outputting signals, receiving voltages and the like, but also multiple bonding pads 20 to 23 (hereinafter referred to as trim pads) for trimming are provided.

These trim pads constitute trim pad units 7A to 7C in a manner that, for example, three trim pads constitute each of the trim pad units 7A to 7C. Note that each of the trim pad units 7A to 7C consists of three trim pads for simplicity in this embodiment, but the number of trim pads constituting each trim pad unit is not limited to three.

Depending on the category information pieces assigned to the respective electronic components 5, different bump layouts are employed so that bumps are formed on certain ones of the trim pads 20 to 23 in these trim pad units 7A to 7C. Thereby, bonding options between the respective electronic components 5 and the corresponding circuit boards are selected, and consequently the functions of the electronic components 5 can be restored, or characteristics thereof can be uniformed.

Then, on the basis of the electrical test result, a mapping data set on the electronic components 5 on the wafer 1 is generated (ST2). The mapping data set is uploaded to the host computer 3, and stored into, for example, a memory 3M in the host computer 3.

The mapping data set consists of a wafer number assigned to the wafer 1, position information on the electronic components 5 (chips) that is based on the x-y coordinate system on the wafer 1, and category information pieces assigned to the respective electronic components 5 based on the electrical test result. Moreover, the mapping data set may further include product name information on the electronic components 5.

The mapping data set on the electronic components 5 on the wafer 1 is generated on the basis of the electrical test that is sequentially performed at wafer level in the x and y directions. Accordingly, in the mapping data set in this stage, a position information piece on any one of the electronic components 5 on the wafer 1 exactly corresponds to the category information piece assigned to the electronic component 5.

Next, the back surface of the wafer 1 is ground so that the wafer 1 can have a predetermined thickness, for example.

Thereafter, the mapping data set including the category information stored in the host computer 3 is supplied to the bumping machine 4. In response, the bumping machine 4 employs various bump layouts for the electronic components 5 on the wafer 1 depending on the assigned category information pieces, and thereby forms bumps on certain ones of the pads 6 and 20 to 23 on the electronic components 5 (ST3).

In this bumping process, the electronic components 5 have not been separated into individual chips yet, and, under such condition, each of these electronic components 5 are bumped depending on the assigned category information piece. This means that the electronic components 5 can be categorized at wafer level where the position information on the electronic components 5 retains accuracy.

Moreover in this bumping process, depending on the category information pieces assigned to the respective electronic components 5, various bump layouts are employed for the electronic components 5 at predetermined positions based on the position information, and thereby bumps are formed on certain ones of the trim pads 20 to 23 on the electronic components 5. This means that, in this bumping process, trimming is performed on the multiple electronic components 5 on the wafer 1 so as to restore functions thereof, or to uniform the operation characteristics thereof.

In other words, in this embodiment, the electronic components 5 are bumped in various bump layouts employed depending on the assigned categories and thereby bonding options are selected for the respective electronic components 5, at wafer level.

Incidentally, in a semiconductor device in which an electronic component (chip) is flip-chip bonded to a circuit board, bumped pads on the electronic component are connected to pads on the circuit board while unbumped pads on the electronic component is not connected to the circuit board.

This means that, in this embodiment, it is possible to select a connection condition (a bonding option) between an electronic component and a circuit board to be flip-chip bonded together in a subsequent process by determining which bump layout to employ in the electronic component. Accordingly, electrical characteristics of the electronic component can be changed by a simple method of employing a different bump layout in the electronic component.

Accordingly, in this embodiment, trimming for restoring functions of the electrical components 5 and for uniforming the operation characteristics thereof can be performed at low cost.

Note that no bump needs to be formed on the bonding pads on the completely defective electronic components 5, which cannot be repaired even if the bump layouts are changed.

After each of the electronic components 5 except for the completely defective ones is bumped, the wafer 1 is diced into individual chips corresponding to the respective electronic components 5 by, for example, blade dicing (ST4).

Thereafter, each of the chip electronic components 5 is picked up from dicing tape, and a flip-chip bonding apparatus (not shown) performs flip-chip bonding between the bumps on the front surface of the chip and pads on the front surface of the circuit board (ST5).

Note that, in the bumping process (ST3) where the position information on the electronic components 5 retains accuracy, the electronic components 5 are categorized and the bonding options are selected for the electronic components 5 according to these categories, respectively. Accordingly, in this flip-chip bonding process (ST5), no such categorization and bonding-option selection is necessary.

Thus, it is not necessary for the flip-chip bonding apparatus to recognize which categories are assigned to the respective electronic components 5.

As is conventional, in a case where chips are categorized after the chips are diced from a wafer and then picked up from dicing tape, the chips are categorized under a condition where the position information on the chips has lost accuracy. This is because the dicing tape is stretched while the chips are picked up so that a space necessary for picking up a chip can be secured between each adjacent two chips, and the deflection and the like of the stretched dicing tape deteriorate the accuracy of the position information on the chips.

Moreover, in a case where electronic components are picked up according to categories, chips surrounding a certain chip are picked up in a random order. This obscures the position relationship between a certain chip and its surrounding chips, thus further deteriorating the accuracy of the position information on the chips.

Furthermore, this leads to the deterioration of accuracy in categorizing the electronic components, and consequently reduces a production yield of semiconductor devices.

In contrast, in this embodiment, the electronic components 5 are respectively bumped depending on the assigned category information pieces included in the mapping data set, in the bumping process which is performed at wafer level. This means that the electronic components 5 are categorized in this process.

Thus, according to this embodiment, it is possible to categorize electronic components at wafer level where the position information retains accuracy, and thereby to improve a production yield of semiconductor devices.

Moreover, the mapping data set may also be downloaded to and thus recognized by the flip-chip bonding apparatus so that the flip-chip bonding apparatus can be prevented from picking up the completely defective electronic components 5. Alternatively, the completely defective electronic components 5 may be marked with ink before the flip-chip bonding process so that the flip-chip bonding apparatus can optically recognize the ink marks so as to be prevented from picking up the completely defective electronic components 5.

By the aforementioned manufacturing method, the semiconductor device in which an electronic component is flip-chip bonded to a circuit board is manufactured.

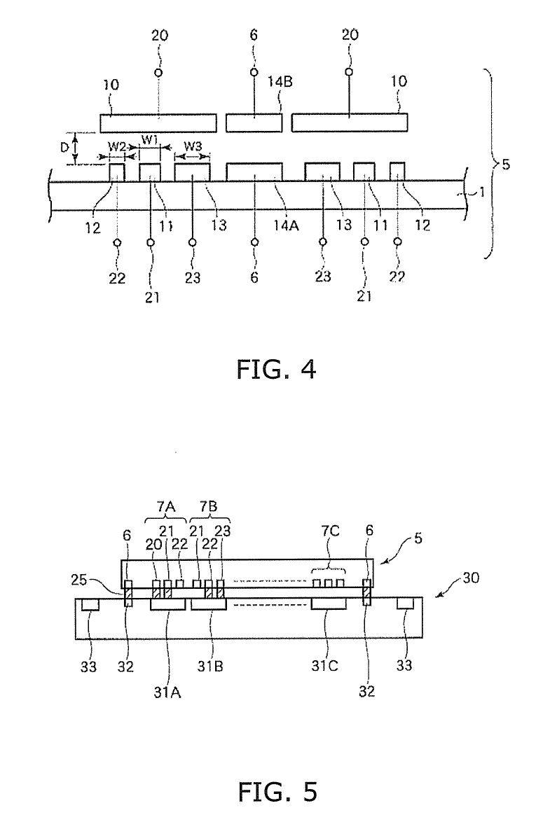

Hereinafter, description will be given of a semiconductor device manufactured by the manufacturing method according to this embodiment, with reference to FIGS. 4 and 5. Note that, in the following description, a MEMS device is used as an example of an electronic component.

In the MEMS device, interdigitated (comb-like) structures consisting of actuation electrodes are provided on a chip, for example. FIG. 4 is an enlarged view showing a pair of interdigitated electrodes which is configured of capacitor electrodes 14A and 14B, upper actuation electrodes 10 and lower actuation electrodes 11 to 13.

Each of the capacitor electrodes 14A and 14B is connected to a certain one of the normal pad 6 through an interconnection layer (not shown), for example. The interdigitated electrodes serving as actuation electrodes control a distance D between the capacitor electrodes 14A and 14B.

The lower actuation electrodes 11 to 13 are disposed on the chip 5, and the upper actuation electrodes 10 are disposed on the lower actuation electrodes 11 to 13 the distance D apart from one another. The lower actuation electrodes 11 to 13 have different width W1 to W3, respectively.

The upper actuation electrodes 10 are connected to the pad 20 in the trim pad unit 7A shown in FIG. 3 through the interconnection layer (not shown), for example.

The lower actuation electrodes 13 are connected to the pad 23 in the trim pad unit 7B shown in FIG. 3 through the interconnection layer (not shown), for example.

Meanwhile, the lower actuation electrodes 11 and 12 are connected to both the trim pad units 7A and 7B through the interconnection layer (not shown), for example. Specifically, each of the lower actuation electrodes 11 is connected to the pads 21 in both the trim pad units 7A and 7B, while each of the lower actuation electrodes 12 is connected to the pads 22 in both the trim pad units 7A and 7B.

Here, a ground voltage, for example, is applied to the trim pad unit 7A, and an actuation voltage, for example, is applied to the trim pad unit 7B. Accordingly, depending on which pad is bumped, either a ground voltage or a actuation voltage is applied to the lower actuation electrodes 11 and 12 connected to the pads 21 and 22 provided in both the trim pad units 7A and 7B. Accordingly, actuation voltages to be applied to the respective electronic components 5 are adjusted such that multiple electronic components 5 have substantially uniform characteristics. Note that multiple sets of interdigitated electrodes and capacitor electrodes as shown in FIG. 4 are provided in each electronic component 5.

FIG. 5 shows a structure in which the chip (electronic component) 5 is flip-chip bonded to a circuit board 30.

The circuit board 30 has bonding pads 31A to 31C, 32 and 33, for example. The bonding pads 31A to 31C (hereinafter, referred to as substrate trim pads) face the trim pad units of the chip 5 on a one-to-one basis. The bonding pads 32 (hereinafter, referred to as substrate normal pads) are connected to the normal pads 6 of the chip 5 on a one-to-one basis. The bonding pads 33 (hereinafter, referred to as external connection pads) are connected to external devices (not shown) or the like by wire bonding. Note that any circuit board that allows the chip (electronic component) 5 to be flip-chip bonded thereto can serve as the circuit board 30. Accordingly, as the circuit board 30, a ball grid array (BGA) substrate may be used in which the back surface thereof is provided with solder balls to be connected to external devices.

As shown in FIG. 5, a bump 25 is formed on the trim pad 20 in the trim pad unit 7A, so that the trim pad 20 is connected to the substrate trim pad 31A. Thereby, a ground voltage is applied to the upper actuation electrodes 10 through the substrate trim pad 31A.

Meanwhile, the bump 25 is formed on the trim pad 23 in the trim pad unit 7B, so that the trim pad 23 is connected to the substrate trim pad 31B. Thereby, an actuation voltage is applied to the lower actuation electrodes 13 through the substrate trim pad 31B.

Moreover, no bump is formed on the trim pad 21 in the trim pad unit 7B, while the bump 25 is formed on the trim pad 21 in the trim pad unit 7A, so that the trim pad 21 is connected to the substrate trim pad 31A.

Accordingly, a ground voltage is supplied to the lower actuation electrodes 11 as similar to the upper actuation electrodes 10, for example.

Meanwhile, no bump is formed on the trim pad 22 in the trim pad unit 7A, while the bump 25 is formed on the trim pad 22 in the trim pad unit 7B, so that the trim pad 22 is connected to the substrate trim pad 31B.

Accordingly, an actuation voltage is supplied to the lower actuation electrodes 12 as similar to the lower actuation electrodes 13, for example.

Additionally, no bump is formed on the pads constituting the trim pad unit 7C, and accordingly, the trim pad unit 7C is not connected to the pad 31C on the circuit board 30.

Hereinbelow, it is assumed that a category corresponds to a bonding option in which an electronic component is connected to a circuit board in the bump layout as shown in FIG. 5 is, for example, a category A.

In the case where an electronic component 5 is a MEMS device as described above, it is so miniaturized that mechanical variations can occur in the distance D between the upper actuation electrodes 10 and the lower actuation electrodes 11 to 13 as well as in each of the sizes (widths W1 to W3) of the respective lower actuation electrodes 11 to 13.

These mechanical variations cause each of effective actuation voltages respectively applied to the upper actuation electrodes 10 and the lower actuation electrodes 11 to 13 to vary from one electronic component 5 to another. Consequently, even electronic components 5 (chips) obtained from a single wafer have different electrical characteristics from one another.

Therefore, it is effective to employ various bumping layouts for the electronic components 5 depending on the assigned categories, and thereby to uniform the characteristics of the electronic components 5 as in this embodiment.

For example, suppose the case where the mapping data set includes, as a category information piece on an electronic component 5 at a certain position on the wafer 1, an information piece representing a category (for example, assumed to be a category B) indicating that the electronic component 5 can receive a larger effective actuation voltage than that of the category A. In this case, a bump layout different from that corresponding to the category A is employed for the electronic component 5 so that the bump 25 can be formed in each of the trim pads 21 and 22 in the trim pad unit 7B. Thereby, an actuation voltage is applied to each of three pairs of lower actuation electrodes 11 to 13, so that a larger effective actuation voltage is supplied to the electronic component 5.

Meanwhile, in the case where the category information piece included in the mapping data set represents a category (for example, assumed to be a category C) indicating that the electronic component 5 can receive a smaller effective actuation voltage than that of the category A, a bump layout different from that corresponding to the category A is employed for the electronic component 5 so that the bump 25 can be formed in each of the trim pads 21 and 22 in the trim pad unit 7A. Thereby, an actuation voltage is applied only to the lower actuation electrodes 13 while a ground voltage is applied to each pair of the lower actuation electrodes 11 and 12, so that a smaller effective actuation voltage is supplied to the electronic component 5.

Alternatively, a smaller effective actuation voltage than that of the category A may be supplied to the electronic component 5 as follows. Firstly, a category corresponds to a bonding option in which the bumps 25 are formed on the trim pads 21 and 23 in the trim pad unit 7B and the trim pad 22 in the trim pad unit 7A, respectively, is set, for example. By assigning the electronic component 5 this category, the bumps 25 may be formed in the electronic component 5 so that an actuation voltage can be applied to each pair of the lower actuation electrodes 11 and 13 and that a ground voltage can be applied to the lower actuation electrodes 12.

Moreover, if, for example, the electronic component 5 can receive a still larger effective actuation voltage than that of the categories A and B, a category corresponds to such a bonding option that allows multiple pairs of interdigitated electrodes to be driven may be set. By assigning the electronic component 5 this category, the bump 25 may be formed on any pad in the trim pad unit 7C so that an additional actuation voltage can be applied to the electronic component 5 therethrough.

Meanwhile, no bump needs to be formed on the bonding pads on the electronic components 5 that are completely defective (of the category D) since such electronic components 5 cannot be repaired even if the bump layouts are changed.

Note that an interconnection structure between the actuation electrodes and the bonding pads is not limited to the aforementioned connection relationship.

As described above, the electronic components 5 are respectively bumped in various bump layouts employed depending on the mapping data set including the category information, in the bumping process.

Thus, it is possible to change, depending on the category assigned to the electronic component, the connection condition between a circuit board and an electronic component 5 to be flip-chip bonded thereto by determining which trim pad on the electronic component 5 to bump.

Accordingly, trimming for uniforming drive characteristics of electrical components 5 or the like can be performed at low cost, according to this embodiment.

In the case where the electronic component 5 in the wafer 1 are MEMS devices as in the aforementioned example, the manufacturing method according to this embodiment is especially effective in uniforming characteristics of the multiple electronic components 5 on the single wafer 1. This is because trimming performed on the electronic components 5 in order to provide them predetermined characteristics can also compensate for characteristic variations in the electronic components 5 attributable to the electrical mechanical variations thereof.

Moreover, in this embodiment, a bumping process is performed at wafer level instead of after the electronic components 5 are separated into individual chips. This makes it possible to bump the electronic components 5 under a condition where the position information on the electronic components 5 retains accuracy.

As a result, the present invention makes it possible to improve a production yield of semiconductor devices in which the electronic components 5 are flip-chip bonded to the circuit boards 30.

As described above, in this embodiment, the mapping data set including the category information pieces on the respective electronic components 5 is firstly generated on the basis of the electrical test performed at wafer level. Then, before being separated into individual chips, the electronic components 5 on the wafer 1 are bumped in various bump layouts employed depending on the assigned categories based on the mapping data set, at wafer level. Thereafter, the electronic components 5 are separated into individual chips, and the resultant chips are, for example, flip-chip bonded to the circuit board 30.

Thus, according to this embodiment, the electronic components 5 can be categorized at wafer level where the position information retains accuracy.

Moreover, in this embodiment, the electronic components 5 are bumped in various bump layouts employed depending on the assigned categories based on the electrical test performed at wafer level. In other words, in this embodiment, it is possible to change the connection condition between the circuit board and the electronic component by determining which trim pad in the semiconductor device to bump. This means that trimming can be performed on a semiconductor device by a simple method.

As described above, according to this embodiment, trimming for restoring functions of the electrical components 5 can be performed at low cost. The manufacturing method according to this embodiment is especially effective against electronic components that are quite likely to have characteristic variations attributable to the mechanical variations thereof, such as MEMS devices, and thus makes it possible to improve a production yield of semiconductor devices having such electronic components.

### SECOND EMBODIMENT

In the second embodiment, a bumping machine will be explained.

One of the characteristics of the aforementioned manufacturing method according to this embodiment is that the mapping data set including the category information is supplied from the host computer 3 to the bumping machine 4, and that thereby, the bumping machine 4 bumps the electronic components 5 in various bump layouts employed depending on the assigned categories.

This requires the bumping machine 4 to be capable of receiving and storing therein information on such bump layouts corresponding to the respective categories that define which pad to bump (hereinafter such information is referred to as bump layout information).

Hereinafter, description will be given of the bumping machine 4 capable of receiving a mapping data set including category information, and bump layout information.

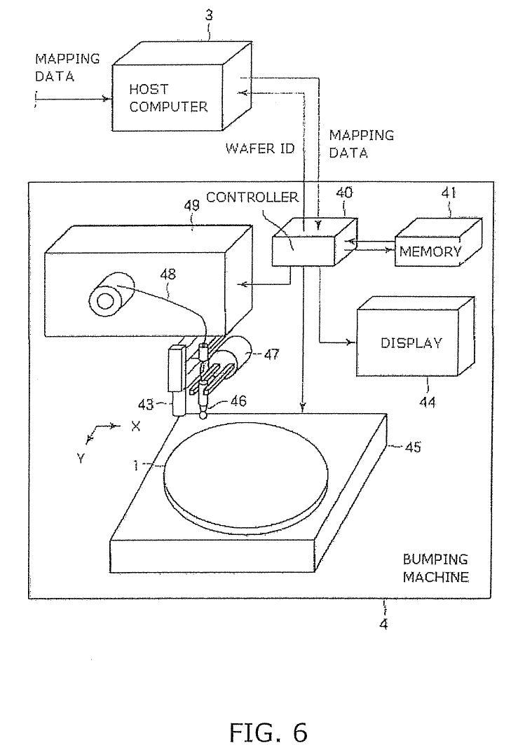

A configuration of the bumping machine 4 employed in this embodiment will be described with reference to FIG. 6.

The bumping machine 4 shown in FIG. 6 is, for example, a stud bumping machine that forms Au bumps on chips.

The bumping machine 4 includes a controller 40 that controls overall operation of the bumping machine 4. The controller 40 is capable of inputting and outputting data to and from the host computer 3. For example, the controller 40 uploads (transmits), to the host computer 3, the wafer number of the wafer 1 read with a camera (an image capture unit). In response, the mapping data set including the category information based on the wafer number is downloaded to (supplied to and received by) the controller 40, from the host computer 3.

The bumping machine 4 further includes a memory 41, and the memory 41 stores, therein, the bump layout information on the multiple electronic components 5.

On the basis of the bump layout information and the mapping data set, the controller 40 controls a bonder unit 49 equipped with a wafer mounting stage 45, a capillary 46 and an ultrasonic oscillator 47. Thereby, bumps are formed on certain ones of the pads on the electronic components 5 on the wafer 1.

On the wafer mounting stage 45, the wafer 1 on which multiple electronic components 5 are formed is mounted. The controller 40 moves the wafer mounting stage 45 in the x and y directions so as to align, with a bump layout, bump material (an Au wire) 48 led out of the tip of the capillary 46.

The Au wire 48 is led out of the capillary 46, and the tip of the led-out Au wire 48 is fused and pressed onto a pad at a predetermined position on the bump layout, by the capillary 46. Then, the ultrasonic oscillator 47 applies ultrasonic vibration to the tip of the Au wire 48 through the capillary 46, and the ultrasonic vibration acts on the Au wire so that the Au wire and a pad on an electronic component 5 are bonded together. Thereby a stud bump is supplied to and formed on the pad.

Moreover, the bumping machine 4 further includes, for example, a display (display unit) 44 that displays images captured by the camera 43. The images displayed on the display 44 include images captured during the alignment, and images showing bond condition between a bump and a pad.

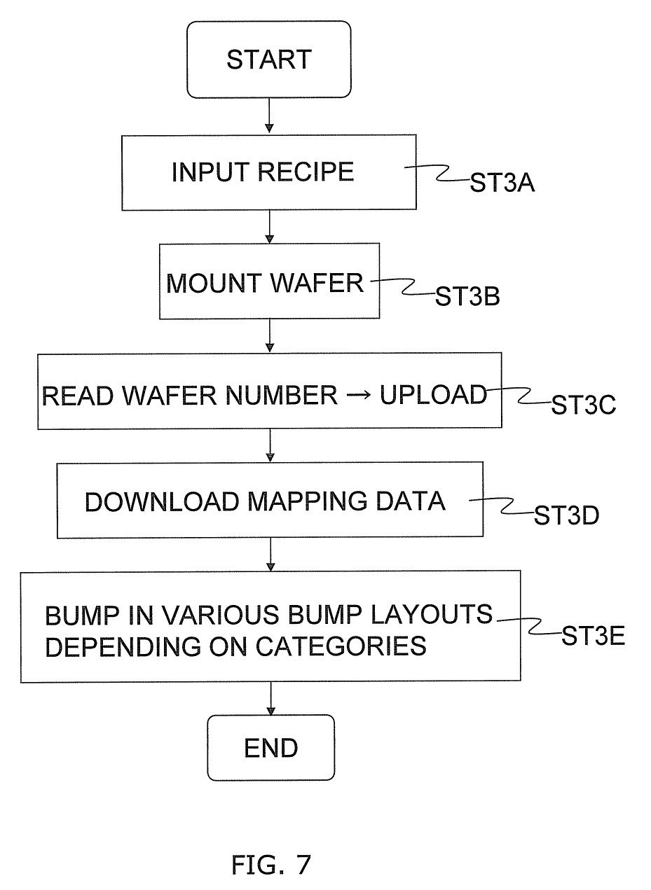

Hereinafter, an operation flow of the bumping machine 4 will be described with reference to FIG. 7.

Firstly, the bumping machine 4 receives the product name information and the bump layout information on the electronic components 5, the bump layout information representing the bump layouts corresponding to the respective categories (ST3A). Hereinbelow, data consisting of the product name information and the bump layout information will be referred to as a recipe. The recipe is stored in the memory 41 provided in the bumping machine 4.

As described above, the recipe is stored in the memory 41 in the bumping machine 4 according to this embodiment. This makes it possible to provide stud bump layout information that represents the bump layouts corresponding to the respective categories to multiple electronic components 5 with the same name.

Next, the wafer 1 is mounted on the wafer mounting stage 45 in the bumping machine 4 (ST3B). Then, the wafer number of the wafer 1 is read by the camera 43, and uploaded from the camera 43 to the host computer 3 (ST3C). Note that the way of uploading the wafer number is not limited to the above way by reading it with the camera 43. For example, an external apparatus (not shown) connected to the controller 40 may be provided. In this case, the wafer number may be inputted through the external input device, be recognized by the controller 40, and then be uploaded to the host computer 3.

Subsequently, the controller 40 searches a mapping database in the host computer 3 for the mapping data set corresponding to the uploaded wafer number. Specifically, the controller 40 checks a wafer number of each mapping data set in the mapping database against the uploaded wafer number. Then, a mapping data set having a wafer number identical to the uploaded wafer number is downloaded to the bumping machine 4 (ST3D).

As has been described, the mapping data sets each are information based on an electrical test result obtained at wafer level, and correspond to respective wafers. Moreover, each mapping data set consists of a wafer number, position information pieces representing positions of respective electronic components in a wafer, and category information pieces of the respective electronic components at these positions. Moreover, each mapping data may further include product name information.

Thereafter, the mapping data set downloaded to the bumping machine 4 is supplied to the controller 40 therein. The controller 40 searches recipes in the memory 41 with reference to the product name information included in the downloaded mapping data set, and thus reads out a recipe having product name information identical to the product name information included in the downloaded mapping data set.

Then, the controller 40 controls the wafer mounting stage 45 and the bonder unit 49, in accordance with the position information and the category information included in the mapping data set, as well as the bump layout information included in the recipe. Thereby, the controller 40 forms stud bumps on certain ones of trim pads on chips in the wafer in various bump layouts employed depending on the category information pieces assigned to the respective electronic components (ST3E). At the same time, a bump is formed on each normal pad on the electronic components. During this process, the display 44 displays images captured by the camera 43, such as positions of the respective electronic components, the alignment of the tip of the bump material 48 with a pad on a electronic component, and bond condition between a bump and a pad.

Note that completely defective electronic components, which cannot be repaired even if the bump layouts are changed, should preferably be not bumped in the bumping process in order to be prevented from being bonded to circuit boards in the flip-chip bonding process. In this embodiment, this can be implemented by associating, as bump layout information, information that indicates no bumping should be performed with a category indicating that the electronic component is completely defective. This is because the bumping machine 4 according to this embodiment is capable of employing various bump layouts depending on the respective categories.

As described above, the bumping machine 4 according to this embodiment is capable of bumping electronic components in various bump layouts depending on the categories assigned to the electronic components. Thus, the bumping machine 4 according to this embodiment is capable of recognizing the categories assigned to the respective electronic components by referring to the corresponding mapping data set, and bumping the electronic components in the bump layouts employed depending on these categories. This means that in this embodiment, electronic components in a wafer can be categorized at wafer level where the position information on the electronic components retains accuracy.

After bumping the electronic components on the wafer 1, a wafer dicing process is performed so that the electronic components are separated into individual chips. These chip electronic component are flip-chip bonded to circuit boards, respectively, and thereby semiconductor devices are manufactured.

In this embodiment, various bump layouts are employed for the respective electronic components depending on the category information pieces assigned on the basis of their electrical test result, and thereby the electronic components are bumped in these various bump layouts, respectively, in the bumping process performed at wafer level where the position information retains accuracy.

This means that the electronic components are categorized in the bumping process. Accordingly, it is not necessary to recognize which categories are assigned to the respective electronic components in the dicing process and the flip-chip bonding process.

As described above, the semiconductor manufacturing apparatus according to the embodiment of the present invention makes it possible to bump the electronic components 5 on the wafer 1 in various bump layouts depending on the assigned category information pieces, at wafer level.

This means that the electronic components can be categorized at wafer level where the position information retains accuracy.

Moreover, the semiconductor manufacturing apparatus according to the embodiment of the present invention makes it possible to change the connection condition between a circuit board and an electronic component at the same time in the bumping process by determining which trim pad on the electronic component to bump. Thus, trimming for restoring the functions of the electrical components and for uniforming drive characteristics thereof can be performed at low cost. The semiconductor manufacturing apparatus according to this embodiment is especially effective against electronic components that are quite likely to have mechanical variations, such as MEMS devices. This is because trimming performed on the electronic components in order to provide them predetermined characteristics can also compensate for characteristic variations in the electronic components.

The bumping machine 4 according to this embodiment makes it possible to perform the bumping process at a wafer level instead of after the electronic components are separated into individual chips. Accordingly, the bumping process can be performed at wafer level where the position information on the electronic components retains accuracy.

As a result, the present invention makes it possible to improve a production yield of semiconductor devices.

### Modification

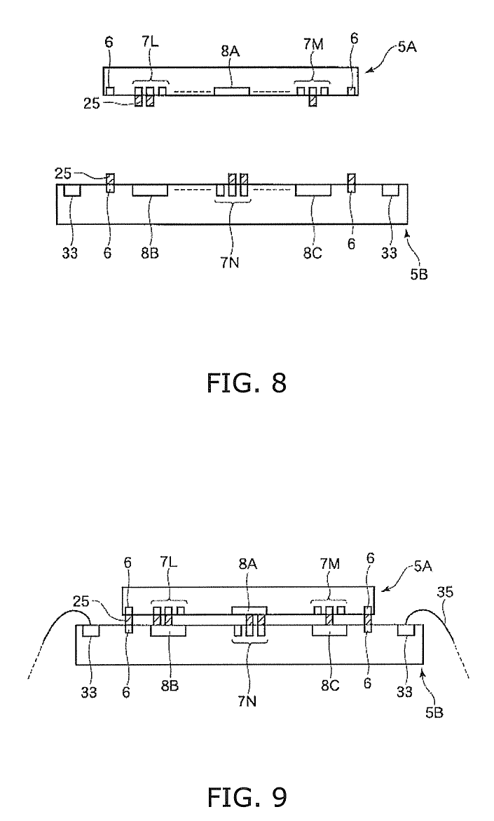

Hereinafter, description will be given of a modification of the embodiment of the present invention with reference to FIGS. 8 and 9. Note that the same constituents as the aforementioned embodiment are denoted by the same reference numerals, and the detailed description thereof will be omitted.

In the aforementioned embodiment, description has been given of the case where an electronic component is flip-chip bonded to a circuit board. However, the embodiment of the present invention is not limited to this, and may include the case where the multiple electronic components 5 manufactured by the aforementioned manufacturing method are flip-chip bonded together.

Hereinbelow, the modification will be more specifically described with reference to FIGS. 8 and 9. Note that, in the modification, electronic components 5A and 5B are described as a MEMS device and a driver LSI for driving the MEMS device, respectively, as an example.

The two electronic components shown in FIG. 8, which are the electronic component (MEMS) 5A and the electronic component (driver LSI) 5B, are manufactured by the aforementioned manufacturing method. Specifically, for multiple electronic components 5A in a wafer, various bump layouts are employed depending on the assigned categories based on the corresponding mapping data set including category information, and thereby bumps 25 are formed on certain ones of pads in trim pad units 7L to 7N, at wafer level. Moreover, the multiple electronic components 5B in another wafer are bumped as similar to these electronic components 5A. Thereby, the multiple electronic components 5A and 5B on the respective wafers are categorized at wafer level where the position information retains accuracy. The wafer on which the electronic components 5A are formed is diced into the multiple chip electronic components 5A, while the wafer on which the electronic components 5B are formed is diced into the multiple chip electronic components 5B.

In the case where the electronic components 5B are LSIs such as driver LSIs as in this modification, the electronic components 5B may be bumped in various bump layouts employed depending on the assigned category information piece so that drive characteristics of the electronic components 5B can be uniformed in the single wafer, as similar to the aforementioned case of MEMS. Note that, however, the electronic components 5B may be bumped in various bump layouts employed depending on the assigned category information piece so that the electronic components 5B with different drive characteristics can be manufactured from the single wafer, instead.

Each of the two electronic components 5A and 5B has trim receiving pads 8A to 8C facing the trim pad units 7L to 7N of the other electronic component on a one-on-one basis.

As shown in FIG. 9, when the two electronic components 5A and 5B are flip-chip bonded together, the trim pad unit 7L of the electronic component 5A is connected to the trim receiving pad 8B of the electronic component 5B through one or more bump 25. Similarly, the trim pad unit units 7M and 7N of the electronic component 5A are connected to the respective trim receiving pads 8A and 8C.

As has been described, the electronic components 5A and 5B are categorized, and bumped in the various bump layouts employed depending on the assigned categories. Thus, it is possible to change connection condition between the two electronic components 5A and 5B by determining which pad on the electronic components 5A and 5B to bump. Thus, trimming can be performed, in such a simple method, on a semiconductor device consisting of the electronic component (MEMS) 5A and electronic component (driver LSI) 5B.

Note that, in the case where two electronic components 5A and 5B are flip-chip bonded together, they are connected to a circuit board (not shown) or an external device (not shown) through external connection pads 33 provided on one of the two electronic components 5A and 5B. Moreover, although FIG. 9 shows an example case in which the electronic component 5B is connected to a circuit board or an external device by wire bonding using wires 35, the semiconductor device consisting of the two electronic components may be flip-chip bonded to the circuit board or the external device.

As described above, in the case where electronic components are flip-chip bonded together, the present invention can provide similar effects as described in the aforementioned embodiment.

Specifically, the present invention makes it possible to categorize electronic components and to change the connection condition between two electronic components to be flip-chip bonded together in a semiconductor device by determining which trim pad on the electronic component to bump, at wafer level where the position information on the electronic components retains accuracy. Thus, trimming can be performed on the semiconductor device in such a simple method.

As described above, according to this modification, the present invention makes it possible to perform trimming for restoring functions of the electrical components, at low cost.

Note that in the modification, description has been given of the example case in which two electronic components manufactured by the method according to the embodiment of the present invention are flip-chip bonded together. However, more than two electronic components may be flip-chip bonded together.

In the embodiment according to the present invention, description has been given of the manufacturing method in the case where a MEMS device is used as an example of an electronic component. Moreover, in this embodiment, description has also been given of the manufacturing method for uniforming drive characteristics of MEMS devices by employing various bump layouts. However, electronic components in the embodiment of the present invention are not limited to MEMS devices, but may be LSIs.

In the case where electronic components are LSIs, it is possible to multiple LSI chips having different drive characteristics from the single chips, by employing various bump layouts for the respective chips obtained from a single chip and thereby selecting bonding options for the respective chips.

Embodiments of the invention have been described with reference to the examples. However, the invention is not limited thereto.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A manufacturing method of a semiconductor device, comprising:
performing an electrical test on a plurality of electronic components on a wafer;
generating a mapping data set including category information representing categories of the respective electronic components based on the electrical test result and position information representing positions of the respective electronic components in the wafer;
forming bumps on the plurality of electronic components at wafer level in various bump layouts employed in accordance with the categories assigned to the respective electronic components, with reference to the mapping data set; and
dicing the wafer to separate the plurality of electronic components into individual chips, after forming the bumps.

2. The manufacturing method of a semiconductor device according to claim 1, further comprising flip-chip bonding one of the individual chips of the electronic components to a circuit board.

3. The manufacturing method of a semiconductor device according to claim 1, wherein in forming the bump, the bumps are not formed on an electronic component that is assigned, and in generating the mapping data set, a category indicating that the electronic component is completely defective.

4. The manufacturing method of a semiconductor device according to claim 1, wherein each of the electronic components is a micro-electro-mechanical systems (MEMS) device including capacitor electrodes and actuation electrodes for controlling a distance between the capacitor electrodes.

5. The manufacturing method of a semiconductor device according to claim 2, wherein in forming the bump, the bumps are not formed on an electronic component that is assigned, and in generating the mapping data set, a category indicating that the electronic component is completely defective.

6. The manufacturing method of a semiconductor device according to claim 1, wherein the bump layout of one of the electronic components are different from the bump layout of another electronic component in the wafer.

7. The manufacturing method of a semiconductor device according to claim 2, wherein the bump layout of one of the electronic components are different from the bump layout of another electronic component in the wafer.

8. The manufacturing method of a semiconductor device according to claim 1, wherein a first bonding pad and a second bonding pad are provided in the respective electronic components, a position of the first bonding pad and the second bonding pad on one of the electronic components is the same as a position of the first bonding pad and the second bonding pad on another the electronic components, the bump is provided on the first bonding pad and the bump is not provided on the second bonding pad.

9. The manufacturing method of a semiconductor device according to claim 8, wherein the second bonding pad is a bonding pad for trimming.

10. The manufacturing method of a semiconductor device according to claim 1, wherein the bump layouts are decided by the electrical characteristic of the respective electronic components.

11. The manufacturing method of a semiconductor device according to claim 2, wherein the bump layouts are decided by the electrical characteristic of the respective electronic components.

12. The manufacturing method of a semiconductor device according to claim 6, wherein the bump layouts are decided by the electrical characteristic of the respective electronic components.

13. The manufacturing method of a semiconductor device according to claim 8, wherein the bump layouts are decided by the electrical characteristic of the respective electronic components.

14. A semiconductor manufacturing apparatus, comprising:
a wafer mounting stage configured to mount thereon a wafer on which a plurality of electronic components are formed;
a bonder unit which supplies a bump material to the plurality of electronic components;
a memory which stores therein bump layout information in association with category information included in the mapping data set on the wafer, the bump layout information representing various bump layouts to be employed in electronic components of the same kind in accordance with the respective categories; and
a controller supplied with the mapping data set and controlling the wafer mounting stage and the bonder unit,
wherein the controller reads out the bump layout information from the memory, and controls the bonder unit and the wafer mounting stage in accordance with the mapping data set and the bump layout information so that the plurality of electronic components are bumped in various bump layouts employed in accordance with the categories assigned to the respective electronic components.
